(19) United States
(12) Patent Application Publication
(10) Pub. No.: US 2018/0174859 A1
(43) Pub. Date: Jun. 21, 2018

(54) ETCHING METHOD

(71) Applicants: BOE TECHNOLOGY GROUP CO., LTD., Beijing (CN); HEFEI BOE OPTOELECTRONICS TECHNOLOGY CO., LTD., Hefei, Anhui Province (CN)

(72) Inventors: Jun ZHANG, Beijing (CN); Yijun WANG, Beijing (CN); Xufei XU, Beijing (CN); Jie SONG, Beijing (CN)

(21) Appl. No.: 15/513,954

(22) PCT Filed: May 31, 2016
(86) PCT No.: PCT/CN2016/084023

§ 371 Date: Mar. 23, 2017

(30) Foreign Application Priority Data
Mar. 21, 2016 (CN) 201610162056.6

(51) Int. Cl. H01L 21/311; H01L 21/027; G03F 7/16; G03F 7/20; G03F 7/30

(52) U.S. Cl. CPC H01L 21/31144; H01L 21/0274; H01L 21/31127; H01L 27/1248; G03F 7/20; G03F 7/30; G03F 7/16

(57) ABSTRACT

It is disclosed an etching method, comprising: applying a photoresist layer on a layer to be patterned; forming a photoresist removing region and a photoresist retaining region on the photoresist layer; forming a cross linking material in the photoresist removing region, and making the cross linking material to react with the photoresist retaining region in predefined conditions to form a reacting region; removing the cross linking material, retaining the photoresist retaining region and the reacting region, and etching a layer in a region where the cross linking material is removed; and removing a shielding layer in the photoresist retaining region and the reacting region to form a patterned layer. Conditions for the reaction between the cross linking material and the photoresist are controlled to modify the width of the reacting region, and a CD smaller than the resolution limit of exposure machine is reached without photoresist residual.

### RELATED APPLICATIONS

The present application is the U.S. national phase entry of PCT/CN2016/084023, with an international filing date of May 31, 2016, which claims the benefit of Chinese Patent Application No. 201610162056.6, filed on Mar. 21, 2016, the entire disclosures of which are incorporated herein by reference.

### TECHNICAL FIELD

The present disclosure relates to the field of display device processing technique, and particularly to an etching method.

### BACKGROUND

Due to the advantages of low power consumption, radiation-free, a liquid crystal display device has become dominant in the field of flat display. In the existing liquid crystal display device, the liquid crystal panel generally comprises an array substrate and a color film substrate which are arranged oppositely, and a liquid crystal layer filled therebetween. The array substrate is provided with a plurality of thin film transistors and a plurality of pixel electrodes. The pixel electrodes are connected with the drain of the thin film transistors. The color film substrate is provided with common electrodes corresponding to the pixel electrodes. When the pixel electrodes are charged through the thin film transistors, an electric field is formed between the pixel electrodes and the common electrodes. The electric filed enables to control the deflection of liquid crystal molecules in the liquid crystal regions to which the pixel electrodes correspond to, thus realizing the display function.

With the development of the flat display technique, there is an increasingly high requirement for PPI (Pixels per Inch) of a display product. This requires continuously reducing CD (Critical Dimension) in the fabricating process. However, the existing design has reached the resolution limit of an exposure machine. In practical process of the liquid crystal panel for forming a hole in an organic insulating film and a hole in PVX, the dimension of the hole is usually so small that it is close to the resolution limit of the exposure machine. The dimension of the hole cannot be further reduced, because otherwise there would be PR (photoresist) residual, in which case the hole could not be formed. Therefore, it is urgent to provide a lithography method which can increase the PPI and competitiveness of a product and can realize lithography of a structure with a smaller CD.

### SUMMARY

It is desired to further increase exposure accuracy on basis of the existing equipment in the art.

The present disclosure provides an etching method, comprising:

applying a photoresist layer on a layer to be patterned;

forming a photoresist removing region and a photoresist retaining region on the photoresist layer;

forming a cross linking material in the photoresist removing region, and making the cross linking material to react with the photoresist retaining region in predefined conditions to form a reacting region;

removing the cross linking material, retaining the photoresist retaining region and the reacting region, and etching a layer in a region where the cross linking material is removed; and

removing a shielding layer in the photoresist retaining region and the reacting region to form a patterned layer.

Optionally, forming the photoresist removing region and the photoresist retaining region on the photoresist layer comprises:

performing exposure and development on the layer on which the photoresist has been applied to form the photoresist removing region and the photoresist retaining region.

Optionally, the predefined conditions comprise reacting at a temperature of 100° C. -300° C.

Optionally, the reacting region has a width which is determined by the duration of reaction.

Optionally, the predefined conditions comprise the duration of reaction of 10 s-200 s.

Optionally, an esterification reaction occurs between the cross linking material and the photoresist.

Optionally, the photoresist is an organic material containing carboxyl.

Optionally, the photoresist comprises phenolic resin.

Optionally, the cross linking material is an organic material containing hydroxyl.

Optionally, the cross linking material is a polymer material containing hydroxyl.

Optionally, the cross linking material is a polymer polyol.

Optionally, the cross linking material has a general formula of CₙH_{2n+2-X}(OH)_{X}.

### BRIEF DESCRIPTION OF THE DRAWINGS

FIG. 1 is a flow chart for the etching method of the present disclosure;

FIG. 2 is a schematic view for illustrating forming a photoresist removing region and a photoresist retaining region in the present disclosure;

FIG. 3 is a schematic view for illustrating forming a cross linking material in the photoresist removing region in the present disclosure;

FIG. 4 is a schematic view for illustrating forming a reacting region in the photoresist removing region in the present disclosure; and

FIG. 5 is a schematic view for illustrating removing the cross linking material in the present disclosure.

### DETAILED DESCRIPTION OF EMBODIMENTS

The specific embodiments of the present disclosure shall be further described in the following text with reference to the figures and the embodiments. The following embodiments are only used for explaining more clearly the technical solution of the present disclosure rather than limiting the protection scope of the present disclosure.

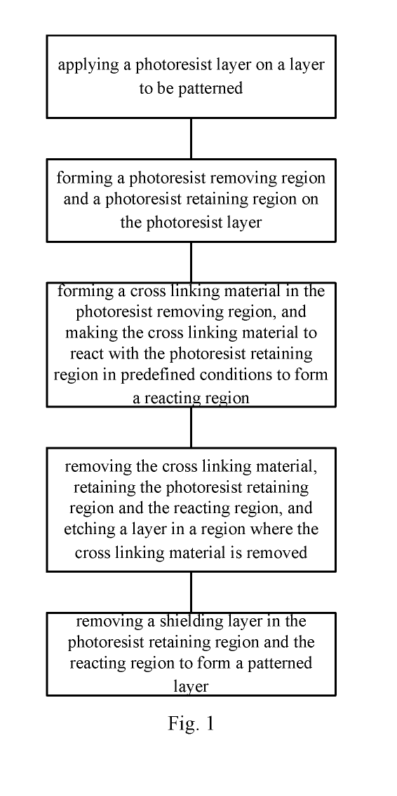

As shown in FIG. 1, the present disclosure provides an etching method, comprising: applying a photoresist layer on a layer to be patterned; forming a photoresist removing region 100 and a photoresist retaining region 101 on the photoresist layer; forming a cross linking material 102 in the photoresist removing region 100, and making the cross linking material 102 to react with the photoresist retaining region 101 in predefined conditions, to form a reacting region 103; removing the cross linking material 102, retaining the photoresist retaining region 101 and the reacting region 103, and etching the layer in a cross linking material removing region 104; and removing a shielding layer in the photoresist retaining region 101 and the reacting region 103 to form a patterned layer. The etching method of the present disclosure will be described in detail hereinafter.

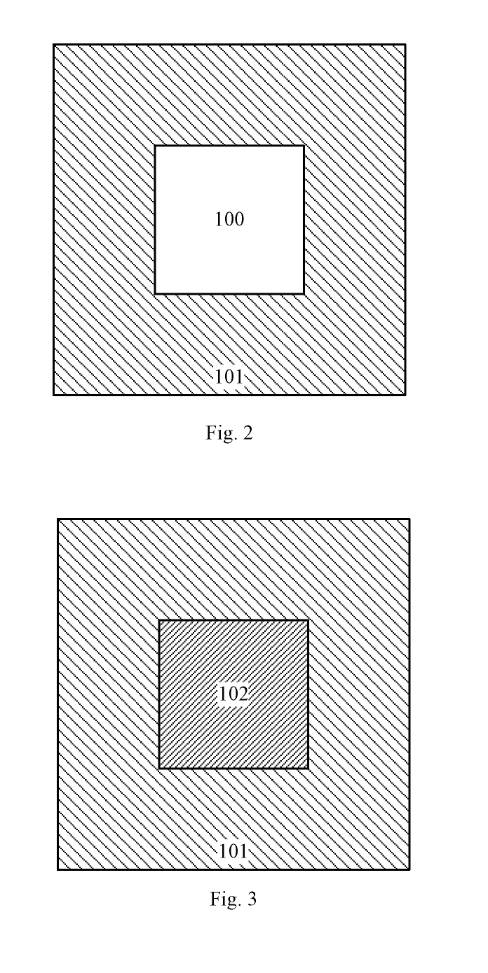

As shown in FIG. 2, photoresist is applied on the layer to be patterned to form a photoresist layer, and exposure and development (first lithography) is performed on the layer on which the photoresist layer has been applied, to form the photoresist removing region 100 and the photoresist retaining region 101 which have a hole shape.

As shown in FIG. 3, after the photoresist removing region 100 and the photoresist retaining region 101 is formed, it is required to fill the photoresist removing region 100 with the cross linking material 102. For purpose of making the photoresist retaining region 101 to chemically react with the cross linking material 102 in specific conditions, according to the property of photoresist, the cross linking material 102 is an organic material containing hydroxyl in an exemplary embodiment, e.g., a polymer material containing hydroxyl. In an embodiment, the cross linking material is a polymer polyol, with a general formula of CₙH_{2n+2-X}(OH)_{X}. In an embodiment, the photoresist is an organic material containing carboxyl, and mainly comprises phenolic resin, an additive photosensitizer and a solvent. The light acid in the photoresist generally exists in the form of R—COOH, which reacts with R′—OH in an esterification reaction in certain conditions. R′ in R′—OH is a high molecular weight material like a chain with a high molecular weight. R′ and —COOH in photoresist form a complex and stable structure, so that the etching rate is changed.

After the photoresist removing region 100 is filled with the cross linking material 102, the filled cross linking material 102 reacts with the photoresist retaining region 101 in certain react conditions. The cross linking material 102 and the photoresist retaining region 101 are fused at a contact interface therebetween to form the reacting region 103. In particular, when the photoresist retaining region 101 and the cross linking material 102 filled in the photoresist removing region 100 are exposed to a high temperature or light irradiation, the photoresist at the contact interface chemically reacts with the cross linking material 102, to form the reacting region 103 with a certain dimension. Since the cross linking material 102 has etching selectivity in specific etching conditions, the etching rate of the cross linking material is much larger than the product of reaction between the photoresist and the reacting region 103, so that the cross linking material can be etched away much more easily.

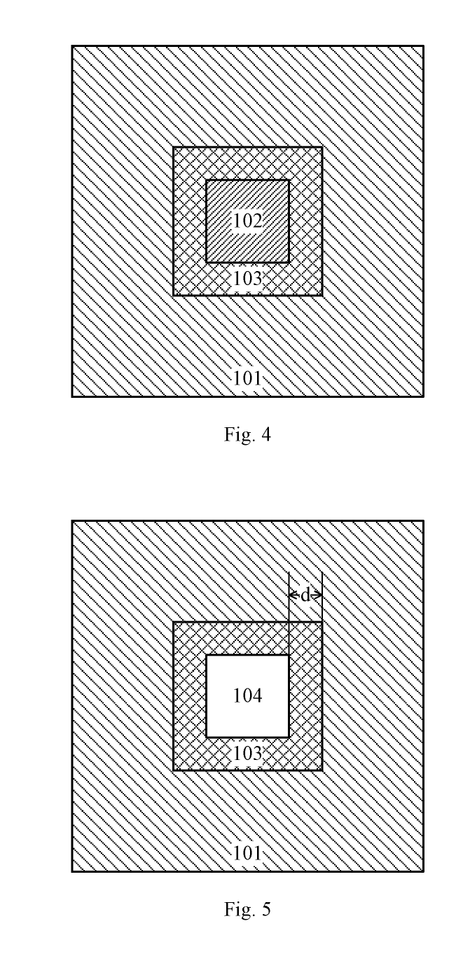

In an embodiment, the filled cross linking material 102 and the layer in the photoresist retaining region 101 are expose to high temperature conditions of for example 100° C.-300° C., and react at the contact interface. The duration of reaction for example is 10 s-200 s. As shown in FIG. 4, the cross linking material 102 and the photoresist retaining region 101 react at the contact interface, to form the reacting region 103 with a certain dimension. The reacting region 103 is formed by the product of reaction between the cross linking material 102 and the photoresist retaining region 101. In specific etching conditions, the cross linking material 102 is etched at a rate much larger than that of the photoresist and the reaction product, so that the cross linking material 102 are etched away much more easily than the photoresist 101 and the reaction product.

As shown in FIG. 5, after the cross linking material 102 and the photoresist retaining region 101 react, an etching step, e.g., dry etching or wet etching, is performed to etch away the cross linking material and to retain the photoresist retaining region 101 and the reacting region 103. Since the cross linking material has an etching selectivity, and has an etching rate which is much larger than that of the photoresist and the reaction product in the reacting region, the photoresist and the reacting region are not etched away in this etching step. Therefore, as compared with the photoresist removing region 100 shown in FIG. 1, the cross linking material removing region 104 of a hole shape has a reduced aperture. As shown in FIG. 5, in an embodiment, the conditions for the reaction between the cross linking material and the photoresist, for example the duration of reaction, are controlled to modify a width d of the reacting region 103, so as to modify the aperture of the cross linking material removing region 104 as needed, and a CD smaller than the resolution limit of exposure machine is reached. The resulting cross linking material removing region 104 of a hole shape has an aperture smaller than the resolution limit of exposure machine without photoresist residual. According to the etching method of the present disclosure, the exposure accuracy can be increased based on the existing equipment, and a structure with a smaller CD can be formed.

Apparently, the person with ordinary skill in the art can make various modifications and variations to the present disclosure without departing from the spirit and the scope of the present disclosure. In this way, provided that these modifications and variations of the present disclosure belong to the scopes of the claims of the present disclosure and the equivalent technologies thereof, the present disclosure also intends to encompass these modifications and variations.

1. An etching method, comprising:
applying a photoresist layer on a layer to be patterned;
forming a photoresist removing region and a photoresist retaining region on the photoresist layer;
forming a cross linking material in the photoresist removing region, and making the cross linking material to react with the photoresist retaining region in predefined conditions to form a reacting region;
removing the cross linking material, retaining the photoresist retaining region and the reacting region, and etching a layer in a region where the cross linking material is removed; and
removing a shielding layer in the photoresist retaining region and the reacting region to form a patterned layer.

2. The etching method of claim 1, wherein forming the photoresist removing region and the photoresist retaining region on the photoresist layer comprises:
performing exposure and development on the layer on which the photoresist has been applied to form the photoresist removing region and the photoresist retaining region.

3. The etching method of claim 1, wherein the predefined conditions comprise reacting at a temperature of 100° C.-300° C.

4. The etching method of claim 1, wherein the reacting region has a width which is determined by the duration of reaction.

5. The etching method of claim 1, wherein the predefined conditions comprise the duration of reaction of 10 s-200 s.

6. The etching method of claim 1, wherein an esterification reaction occurs between the cross linking material and the photoresist.

7. The etching method of claim 1, wherein the photoresist is an organic material containing carboxyl.

8. The etching method of claim 1, wherein the photoresist comprises phenolic resin.

9. The etching method of claim 1, wherein the cross linking material is an organic material containing hydroxyl.

10. The etching method of claim 9, wherein the cross linking material is a polymer material containing hydroxyl.

11. The etching method of claim 1, wherein the cross linking material is a polymer polyol.

12. The etching method of claim 1, wherein the cross linking material has a general formula of CₙH_{2n+2-X}(OH)_{X}.

13. The etching method of claim 7, wherein the photoresist comprises phenolic resin.

14. The etching method of claim 9, wherein the cross linking material has a general formula of CₙH_{2n+2-X}(OH)_{X}.

15. The etching method of claim 10, wherein the cross linking material has a general formula of CₙH_{2n+2-X}(OH)_{X}.

16. The etching method of claim 11, wherein the cross linking material has a general formula of CₙH_{2n+2-X}(OH)_{X}.
